(19) United States
(12) Patent Application Publication
(10) Pub. No.: US 2021/0396787 A1
(43) Pub. Date: Dec. 23, 2021

(54) Digital Input and Output Signal Test Platform

(71) Applicants: Tyco Electronics (Shanghai) Co. Ltd., Shanghai (CN); TE Connectivity Services GmbH, Schaffhausen (CH); Kunshan League Automechanism Co., Ltd., Kunshan City (CN)

(72) Inventors: Lei Zhou, Shanghai (CN); Huabin Du, Shanghai (CN); Dandan Zhang, Shanghai (CN); Roberto Francisco-Yi Lu, Bellevue, WA (US); Lvhai Hu, Shanghai (CN); Du Wen, Middletown, PA (US); Sonny O. Osunkwo, Middletown, PA (US); Haidong Wu, Kunshan City (CN); Zhirong Wan, Kunshan City (CN); Cheng Wang, Kunshan City (CN)

(73) Assignees: Tyco Electronics (Shanghai) Co. Ltd., Shanghai (CN); TE Connectivity Services GmbH, Schaffhausen (CH); Kunshan League Automechanism Co., Ltd., Kunshan City (CN)

(21) Appl. No.: 17/346,704

(22) Filed: Jun. 14, 2021

(30) Foreign Application Priority Data
Jun. 19, 2020 (CN) 202010568186.6

(51) Int. Cl. G01R 19/00; G01R 31/317; G01R 31/3183

(52) U.S. Cl. CPC G01R 19/0038; G01R 31/3183; G01R 31/31715

(57) ABSTRACT

A digital input and output signal test platform includes a digital input signal circuit, a digital output signal circuit, and a digital signal interface circuit. The digital input signal circuit generates a plurality of digital input signals and displays the generated digital input signals. The digital output signal circuit receives a plurality of digital output signals and displays the received digital output signals. The digital signal interface circuit transmits the generated digital input signals to digital input ports of an electronic product under test, and transmits the digital output signals output from digital output ports of the electronic product to the digital output signal circuit.

### CROSS-REFERENCE TO RELATED APPLICATIONS

This application claims priority under 35 U.S.C. § 119 to Chinese Patent Application No. 202010568186.6, filed on Jun. 19, 2020, the entire disclosure of which is incorporated herein by reference.

### FIELD OF THE INVENTION

The present disclosure relates to test platforms for electronic devices, and more specifically, to a digital input and output signal test platform.

### BACKGROUND

During development of digital electronic products, it is necessary to test their digital signal input ports and digital signal output ports. In a relevant art, there is need to develop specialized digital input signal generators for performing these tests for a given type of device under test, for example, a programmable logic controller (PLC). The digital input signal generator generates a plurality of digital input signals, and the plurality of digital input signals generated are transmitted to the digital signal input ports of the electronic products under test. Due to the need for specialized digital input signal generators for various types of devices, development costs of electronic products are increased.

### SUMMARY

According to an embodiment of the present disclosure, a digital input and output signal test platform includes a digital input signal circuit, a digital output signal circuit, and a digital signal interface circuit. The digital input signal circuit generates a plurality of digital input signals and displays the generated digital input signals. The digital output signal circuit receives a plurality of digital output signals and displays the received digital output signals. The digital signal interface circuit transmits the generated digital input signals to digital input ports of an electronic product under test, and transmits the digital output signals output from digital output ports of the electronic product to the digital output signal circuit.

### BRIEF DESCRIPTION OF THE DRAWINGS

The invention will now be described by way of example with reference to the accompanying Figures, of which:

FIG. 1 shows a schematic perspective view of a digital input and output signal test platform according to an exemplary embodiment of the present disclosure;

FIG. 2 shows a schematic perspective view of a digital input signal circuit and a digital output signal circuit of the digital input and output signal test platform as shown in FIG. 1; and

FIG. 3 shows a schematic perspective view of a digital signal interface circuit of the digital input and output signal test platform as shown in FIG. 1.

### DETAILED DESCRIPTION OF THE EMBODIMENTS

Exemplary embodiments of the present disclosure will be described hereinafter in detail with reference to the attached drawings, wherein the like reference numerals refer to the like elements. The present disclosure may, however, be embodied in many different forms and should not be construed as being limited to the embodiment set forth herein; rather, these embodiments are provided so that the present disclosure will be thorough and complete, and will fully convey the concept of the disclosure to those skilled in the art.

In the following detailed description, for purposes of explanation, numerous specific details are set forth in order to provide a thorough understanding of the disclosed embodiments. It will be apparent, however, that one or more embodiments may be practiced without these specific details. In other instances, well-known structures and devices are schematically shown in order to simplify the drawing.

According to an embodiment of the present disclosure, a digital input and output signal test platform includes a digital input signal circuit adapted to generate a plurality of digital input signals and display the generated digital input signals. A digital output signal circuit of the platform receives a plurality of digital output signals and displays the received digital output signals. A digital signal interface circuit is further provided for transmitting the generated digital input signals to digital input ports of an electronic product under test and transmitting the digital output signals output from digital output ports of the electronic product to the digital output signal circuit.

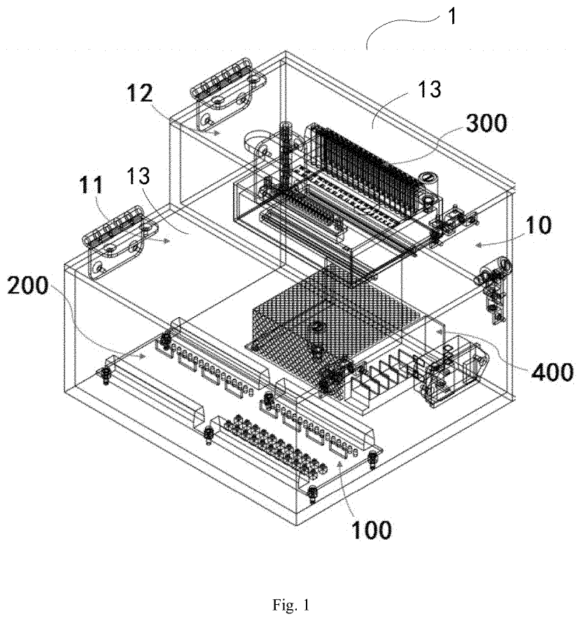

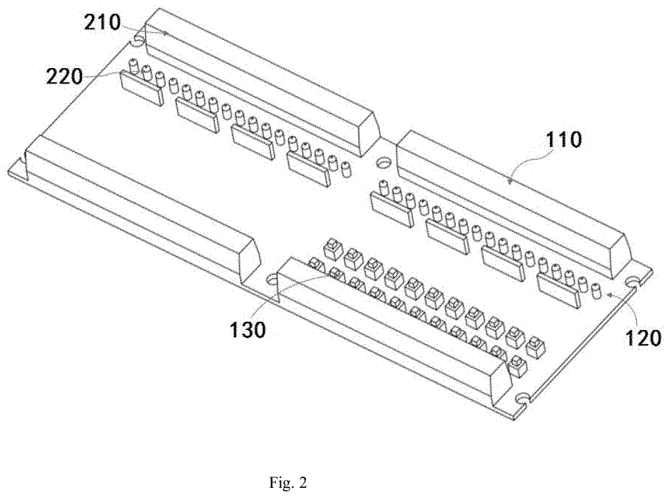

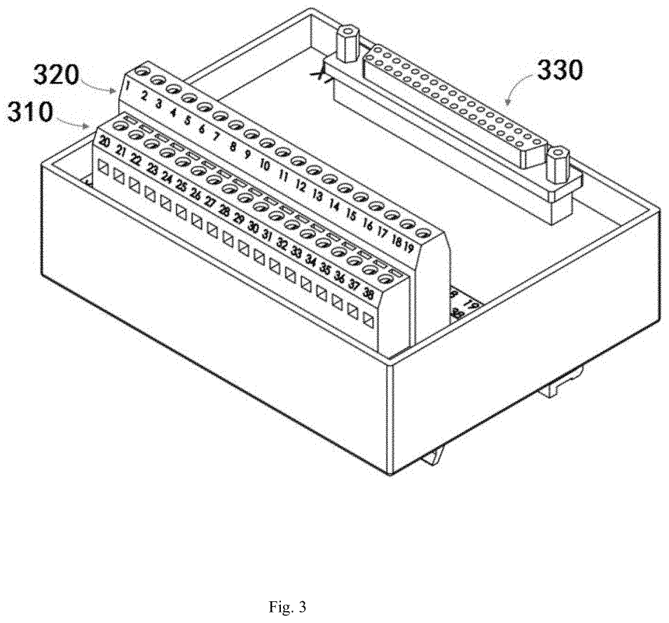

FIG. 1 shows a schematic perspective view of a digital input and output signal test platform 1 according to an exemplary embodiment of the present disclosure; FIG. 2 shows a schematic perspective view of a digital input signal circuit 100 and a digital output signal circuit 200 of the digital input and output signal test platform 1 as shown in FIG. 1; and FIG. 3 shows a schematic perspective view of a digital signal interface circuit 300 of the digital input and output signal test platform 1 as shown in FIG. 1.

As shown in FIGS. 1-3, in an illustrated embodiment, the digital input and output signal test platform 1 generally includes a digital input signal circuit 100, a digital output signal circuit 200 and a digital signal interface circuit 300. The digital input signal circuit 100 is adapted to generate a plurality of digital input signals and display the generated digital input signals. The digital output signal circuit 200 is adapted to receive a plurality of digital output signals and display the received digital output signals. The digital signal interface circuit 300 is configured to transmit the generated digital input signals to digital input ports of an electronic product under test and to transmit the digital output signals output from digital output ports of the electronic product to the digital output signal circuit 200.

As shown in FIGS. 1-3, in the illustrated embodiment, the digital input signal circuit 100 includes a plurality of input signal buttons 130 and a plurality of input signal lights 120. Each of the input signal buttons 130 may be pressed to generate a corresponding digital input signal. The plurality of input signal lights 120 correspond to the plurality of input signal buttons 130 respectively. When one input signal button 130 is pressed, the input signal light 120 corresponding to the input signal button 130 turns on to display a generated digital input signal.

As shown in FIGS. 1-3, in the illustrated embodiment, the digital output signal circuit 200 includes a plurality of output signal lights 220. When a digital output signal is outputted from a digital output port of the electronic product, the output signal light 220 corresponding to the digital output port turns on to display the outputted digital output signal.

As shown in FIGS. 1-3, in the illustrated embodiment, the digital input signal circuit 100 includes a first input signal terminal module 110, and the digital signal interface circuit 300 includes a second input signal terminal module 310. The first input signal terminal module 110 is connected to the second input signal terminal module 310, such that the generated digital input signal can be transmitted from the digital input signal circuit 100 to the digital signal interface circuit 300.

As shown in FIGS. 1-3, in the illustrated embodiment, the digital output signal circuit 200 includes a first output signal terminal module 210, and the digital signal interface circuit 300 includes a second output signal terminal module 320. The first output signal terminal module 210 is connected to the second output signal terminal module 320, so that the digital output signal can be transmitted from the digital signal interface circuit 300 to the digital output signal circuit 200.

As shown in FIGS. 1-3, in the illustrated embodiment, the first input signal terminal module 110 includes a plurality of first input signal terminals respectively corresponding to the plurality of input signal lights 120. The second input signal terminal module 310 includes a plurality of second input signal terminals respectively corresponding to the plurality of first input signal terminals. The plurality of first input signal terminals are connected to the plurality of second input signal terminals respectively.

As shown in FIGS. 1-3, in the illustrated embodiment, the first output signal terminal module 210 includes a plurality of first output signal terminals respectively corresponding to the plurality of output signal lights 220. The second output signal terminal module 320 includes a plurality of second output signal terminals respectively corresponding to the plurality of first output signal terminals. The plurality of first output signal terminals are connected to the plurality of second output signal terminals respectively.

As shown in FIGS. 1-3, in the illustrated embodiment, the digital signal interface circuit 300 includes an input and output interface module 330 adapted to be connected to the digital input port and digital output port of the electronic product. The input and output interface module 330 is configured to connect the plurality of second input signal terminals to the plurality of digital input ports of the electronic product respectively, and to connect the plurality of digital output ports of the electronic product to the plurality of second output signal terminals respectively.

As shown in FIGS. 1-3, in the illustrated embodiment, the number of the input signal buttons 130, the number of the input signal lights 120, the number of the first input signal terminals, the number of the first output signal terminals and the number of the output signal lights 220 are the same.

As shown in FIGS. 1-3, in the illustrated embodiment, each of the number of the input signal buttons 130, the number of the input signal lights 120, the number of the first input signal terminals, the number of the first output signal terminals and the number of the output signal lights 220 is 8, 16, 32 or 64. By way of example, when the number of the input signal buttons 130, the number of the input signal lights 120, the number of the first input signal terminals, the number of the first output signal terminals, and the number of the output signal lights 220 are 16, the digital input and output signal test platform 1 can be used for testing an electronic product with 16 digital input signal ports and 16 digital output signal ports. In this case, the digital input signal and the digital output signal respectively have 2\hat{ }16 or 65536 different statuses, and the input signal light 120 and the output signal light 220 may respectively display 2\hat{ }16 or 65536 different digital input signal states and 2\hat{ }16 or 65536 different digital output signal statuses.

As shown in FIGS. 1-3, in an illustrated embodiment, the digital input and output signal test platform 1 further includes a power module 400 configured to supply power to the digital input signal circuit 100, the digital output signal circuit 200 and the digital signal interface circuit 300.

As shown in FIGS. 1-3, in the illustrated embodiment, the digital input signal circuit 100 and the digital output signal circuit 200 are integrated onto a single circuit board.

As shown in FIGS. 1-3, in the illustrated embodiment, the digital input and output signal test platform 1 further includes a housing 10, in which the digital input signal circuit 100, the digital output signal circuit 200, the power module 400 and the digital signal interface circuit 300 are arranged.

As shown in FIGS. 1-3, in an illustrated embodiment, the housing 10 has an openable and closable top lid. In this way, the digital input signal circuit 100, the digital output signal circuit 200, the digital signal interface circuit 300 and the power module 400 can be mounted or replaced by opening the lid.

As shown in FIGS. 1-3, in the illustrated embodiment, the housing 10 includes a lower accommodating space 11 in which the digital input signal circuit 100, the digital output signal circuit 200 and the power module 400 are accommodated. The housing further includes an upper accommodating space 12 in which the digital signal interface circuit 300 is accommodated and located directly above the power module 400.

As shown in FIGS. 1-3, in the illustrated embodiment, the input signal light 120 and the output signal light 220 may be LEDs.

As shown in FIGS. 1-3, in the illustrated embodiment, the electronic product under test may be an electronic card with a plurality of digital input ports and a plurality of digital output ports. For example, the electronic card may include various types of digital I/O cards.

It should be appreciated for those skilled in this art that the above embodiments are intended to be illustrated, and not restrictive. For example, many modifications may be made to the above embodiments by those skilled in this art, and various features described in different embodiments may be freely combined with each other without conflicting in configuration or principle.

Although several exemplary embodiments have been shown and described, it would be appreciated by those skilled in the art that various changes or modifications may be made in these embodiments without departing from the principles and spirit of the disclosure, the scope of which is defined in the claims and their equivalents.

As used herein, an element recited in the singular and proceeded with the word “a” or “an” should be understood as not excluding plural of said elements or steps, unless such exclusion is explicitly stated. Furthermore, references to “one embodiment” of the present disclosure are not intended to be interpreted as excluding the existence of additional embodiments that also incorporate the recited features. Moreover, unless explicitly stated to the contrary, embodiments “comprising” or “having” an element or a plurality of elements having a particular property may include additional such elements not having that property.

What is claimed is:

1. A digital input and output signal test platform, comprising:
a digital input signal circuit generating a plurality of digital input signals and displaying the generated digital input signals;
a digital output signal circuit receiving a plurality of digital output signals and displaying the received digital output signals; and
a digital signal interface circuit transmitting the generated digital input signals to digital input ports of an electronic product under test and transmitting the digital output signals output from digital output ports of the electronic product to the digital output signal circuit.

2. The digital input and output signal test platform according to claim 1, wherein the digital input signal circuit includes a plurality of input signal buttons adapted to be pressed to generate the digital input signals.

3. The digital input and output signal test platform according to claim 2, wherein the digital input signal circuit further includes a plurality of input signal lights corresponding to the plurality of input signal buttons, in response to one of the input signal buttons being pressed, the input signal light corresponding to the pressed input signal button turns on to display a digital input signal generated by the pressed input signal button.

4. The digital input and output signal test platform according to claim 3, wherein the digital output signal circuit includes a plurality of output signal lights, in response to a digital output signal being output from one of the digital output ports of the electronic product, the output signal light corresponding to the digital output port turns on to display the output digital output signal.

5. The digital input and output signal test platform according to claim 4, wherein the digital input signal circuit includes a first input signal terminal module, and the digital signal interface circuit including a second input signal terminal module, the first input signal terminal module being connected to the second input signal terminal module for transmitting the generated digital input signal from the digital input signal circuit to the digital signal interface circuit.

6. The digital input and output signal test platform according to claim 5, wherein the digital output signal circuit includes a first output signal terminal module, and the digital signal interface circuit includes a second output signal terminal module, the first output signal terminal module being connected to the second output signal terminal module for transmitting the digital output signal from the digital signal interface circuit to the digital output signal circuit.

7. The digital input and output signal test platform according to claim 6, wherein the first input signal terminal module includes a plurality of first input signal terminals corresponding to the plurality of input signal lights, and the second input signal terminal module includes a plurality of second input signal terminals corresponding to the plurality of first input signal terminals, the plurality of first input signal terminals being connected to the plurality of second input signal terminals.

8. The digital input and output signal test platform according to claim 7, wherein the first output signal terminal module includes a plurality of first output signal terminals corresponding to the plurality of output signal lights, and the second output signal terminal module includes a plurality of second output signal terminals corresponding to the plurality of first output signal terminals, the plurality of first output signal terminals being connected to the plurality of second output signal terminals.

9. The digital input and output signal test platform according to claim 8, wherein the digital signal interface circuit includes an input and output interface module for connecting to the digital input port and digital output port of the electronic product.

10. The digital input and output signal test platform according to claim 9, wherein the input and output interface module connects the plurality of second input signal terminals to the plurality of digital input ports of the electronic product, and connects the plurality of digital output ports of the electronic product to the plurality of second output signal terminals.

11. The digital input and output signal test platform according to claim 10, wherein the number of the input signal buttons, the number of the input signal lights, the number of the first input signal terminals, the number of the first output signal terminals and the number of the output signal lights are the same.

12. The digital input and output signal test platform according to claim 11, wherein each of the number of the input signal buttons, the number of the input signal lights, the number of the first input signal terminals, the number of the first output signal terminals and the number of the output signal lights is 8, 16, 32 or 64.

13. The digital input and output signal test platform according to claim 1, further comprising a power module for suppling power to the digital input signal circuit, the digital output signal circuit and the digital signal interface circuit.

14. The digital input and output signal test platform according to claim 13, wherein the digital input signal circuit and the digital output signal circuit are integrated on a single circuit board.

15. The digital input and output signal test platform according to claim 13, further comprising a housing in which the digital input signal circuit, the digital output signal circuit, the power module and the digital signal interface circuit are arranged.

16. The digital input and output signal test platform according to claim 15, wherein the housing has an openable and closable cover for accessing the digital input signal circuit, the digital output signal circuit, the digital signal interface circuit and the power module.

17. The digital input and output signal test platform according to claim 15, wherein the housing includes:
a lower space in which the digital input signal circuit, the digital output signal circuit and the power module are arranged; and
an upper space in which the digital signal interface circuit is arranged and located directly above the power module.

18. The digital input and output signal test platform according to claim 1, wherein the electronic product under test is an electronic card with a plurality of digital input ports and a plurality of digital output ports.

19. A digital input and output signal test platform comprising:
a digital input signal circuit generating a plurality of digital input signals and displaying the generated digital input signals, including:
a plurality of input signal buttons for selectively generating the digital input signals; and
a plurality of input signal lights corresponding to the plurality of input signal buttons, in response to one of the input signal buttons being pressed, the input signal light corresponding to the pressed input signal button turns on to display a digital input signal generated by the pressed input signal button; and
a digital output signal circuit receiving a plurality of digital output signals and displaying the received digital output signals, the digital output signal circuit including a plurality of output signal lights, in response to a digital output signal being output from a digital output port of an electronic product under test, the output signal light corresponding to the digital output port turns on to display the output digital output signal.

20. The digital input and output signal test platform according to claim 19, wherein the digital input signal circuit and the digital output signal circuit are integrated on a single circuit board.
